(19) United States
(12) Patent Application Publication
(10) Pub. No.: US 2025/0377588 A1
(43) Pub. Date: Dec. 11, 2025

(54) RESIST COMPOSITION AND PATTERN FORMING PROCESS

(71) Applicant: Shin-Etsu Chemical Co., Ltd., Tokyo (JP)

(72) Inventors: Satoshi Kusama, Joetsu-shi (JP); Kousuke Ohyama, Joetsu-shi (JP); Shun Kikuchi, Joetsu-shi (JP); Masaki Ohashi, Joetsu-shi (JP)

(73) Assignee: Shin-Etsu Chemical Co., Ltd., Tokyo (JP)

(21) Appl. No.: 19/220,497

(22) Filed: May 28, 2025

(30) Foreign Application Priority Data
Jun. 5, 2024 (JP) 2024-091409

(51) Int. Cl. G03F 7/004; G03F 7/20

(52) U.S. Cl. CPC G03F 7/0042; G03F 7/2004; G03F 7/2059

(57) ABSTRACT

The resist composition comprises a metal complex containing a metal, typically zinc and a specific ligand exhibits a high sensitivity, high resolution and improved LWR when processed by photolithography. The composition is stable during storage and easy to handle. The resist composition comprises a metal complex containing a metal atom and a ligand having the formula (1a), (1b) or (1c). R¹, R², R³, R⁴, R⁵, R⁶ and R⁷ are each independently hydrogen, a C₂-C₂₀ hydrocarbylcarbonyl group which may contain a heteroatom, or C₁-C₂₀ hydrocarbyl group which may contain a heteroatom, *1 and *2 each designate a point of attachment to the metal atom.

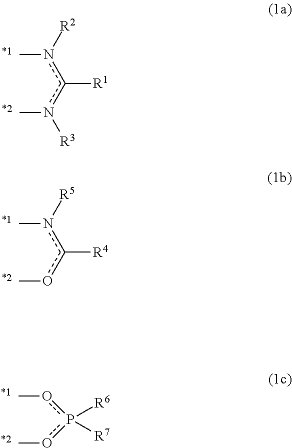

### CROSS-REFERENCE TO RELATED APPLICATIONS

This non-provisional application claims priority under 35 U.S.C. § 119 (a) on Patent Application No. 2024-091409 filed in Japan on Jun. 5, 2024, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite as discussed in the prior art, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EB or EUV exposure. Because of the lack of a cyclic structure, there remain drawbacks like poor etch resistance and noticeable outgassing during exposure.

Hydrogensilsesquioxane (HSQ) is a material for a negative resist composition which turns insoluble in alkaline developer through crosslinking by condensation reaction of silanol generated upon EB or EUV exposure. Also chlorine-substituted calixarene functions as a material for a negative resist composition. Since these materials have a small molecular size prior to crosslinking and avoid any image blur due to acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in the number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device.

As the means for reducing the influence of shot noise on the resist side, Patent Document 1 discloses an inorganic resist composition containing a highly EUV-absorbing element as nucleus. Although the inorganic resist composition has a relatively high sensitivity, it is still unsatisfactory in many aspects including solubility in resist solvents, storage stability, and defectiveness.

Non-Patent Document 3 discloses a negative tone resist composition comprising a tin compound. This non-chemically-amplified resist composition based on tin element having high EUV absorption is improved in stochastics and achieves a high sensitivity and high resolution, but it suffers from many problems including low stability, degradation during shelf storage, and outstanding changes of performance during post PEB delay (PPD).

### CITATION LIST

Patent Document 1: JP-A 2015-108781
Non-Patent Document 1: SPIE Vol. 5039 p1 (2003)
Non-Patent Document 2: SPIE Vol. 6520 p 65203L-1 (2007)
Non-Patent Document 3: SPIE Vol. 9051 p 90511B-1 (2014)

### SUMMARY OF THE INVENTION

An object of the invention is to provide a resist composition which is stable during storage and easy to handle and exhibits a satisfactory sensitivity, resolution and LWR when processed by photolithography using high-energy radiation, typically EB and EUV lithography, and a patterning process using the same.

The inventors have found that a resist composition based on a metal complex having a specific structure exhibits a high sensitivity, improved resolution and reduced LWR, forms a resist film having improved stability, and is thus quite useful in precise micropatterning.

In one aspect, the invention provides a resist composition comprising a metal complex containing a metal atom and a ligand having the formula (1a), (1b) or (1c):

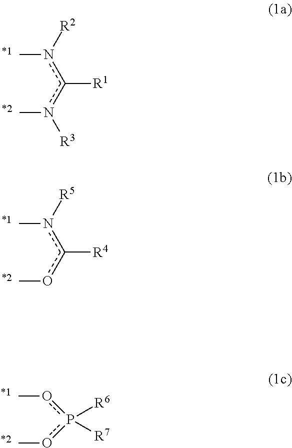

wherein R¹, R², R³, R⁴, R⁵, R⁶ and R⁷ are each independently hydrogen, a C₂-C₂₀ hydrocarbylcarbonyl group which may contain a heteroatom, or C₁-C₂₀ hydrocarbyl group which may contain a heteroatom, *1 and *2 each designate a point of attachment to the metal atom.

Most often, the metal atom is zinc.

In a preferred embodiment, the metal complex is a tetranuclear zinc cluster having the formula (2a):

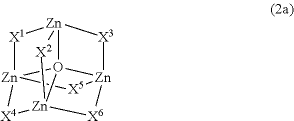

wherein X¹, X², X³, X⁴, X⁵ and X⁶ are each independently a bridging ligand, at least one of X¹, X², X³, X⁴, X⁵ and X⁶ is a ligand having formula (1a), (1b) or (1c).

In another aspect, the invention provides a pattern forming process comprising the steps of applying the resist composition defined herein onto a substrate to form a resist film thereon, exposing the resist film to high-energy radiation, and developing the exposed resist film. Typically, the high-energy radiation is EB or EUV.

### Advantageous Effects of Invention

The resist composition has satisfactory stability and exhibits both high sensitivity and resolution and reduced LWR when processed by EB and EUV lithography processes. The resist composition is quite useful in micropatterning.

### DETAILED DESCRIPTION OF THE INVENTION

The terms “a” and “an” herein do not denote a limitation of quantity, but rather denote the presence of at least one of the referenced item. As used herein, the notation (Cₙ-Cₘ) means a group containing from n to m carbon atoms per group. Me stands for methyl.

The abbreviations and acronyms have the following meaning.
UV: ultraviolet radiation
EUV: extreme ultraviolet
EB: electron beam
Mw: weight average molecular weight
Mw/Mn: polydispersity index
GPC: gel permeation chromatography
PEB: post-exposure bake
LWR: line width roughness
CDU: critical dimension uniformity
PPD: post PEB delay

### [Resist Composition]

One embodiment of the invention is a resist composition comprising a metal complex containing a metal atom and a specific ligand.

### [Metal Complex]

The metal complex contains a metal atom and a ligand having the formula (1a), (1b) or (1c). The ligand has a sufficiently high bond energy with the metal atom to stabilize the complex. This leads to improvements in stability with time of the resist composition during shelf storage and in PPD stability. That is, performance degradation by PPD is minimized.

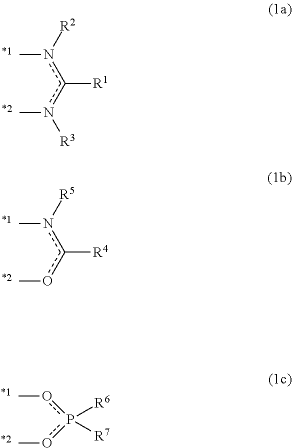

In formulae (1a) to (1c), R¹, R², R³, R⁴, R⁵, R⁶ and R⁷ are each independently hydrogen, a C₂-C₂₀ hydrocarbylcarbonyl group which may contain a heteroatom, or C₁-C₂₀ hydrocarbyl group which may contain a heteroatom. The hydrocarbyl group and hydrocarbyl moiety in the hydrocarbylcarbonyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.02,6]decanyl, adamantyl, and adamantylmethyl, C₂-C₂₀ alkenyl groups such as vinyl and 2-propenyl, C₆-C₂₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂-is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). In the formulae, *1 and *2 each designate a point of attachment to the metal atom.

The ligand having formula (1a), (1b) or (1c) may be either a chelate ligand wherein *1 and *2 are attached to an identical metal atom or a bridging ligand wherein *1 and *2 are attached to different metal atoms. The bridging ligand wherein *1 and *2 are attached to different metal atoms is preferred. The ligand having formula (1a), (1b) or (1c) may be used alone or in admixture of two or more.

Examples of the ligand having formula (1a), (1b) or (1c) are shown below, but not limited thereto.

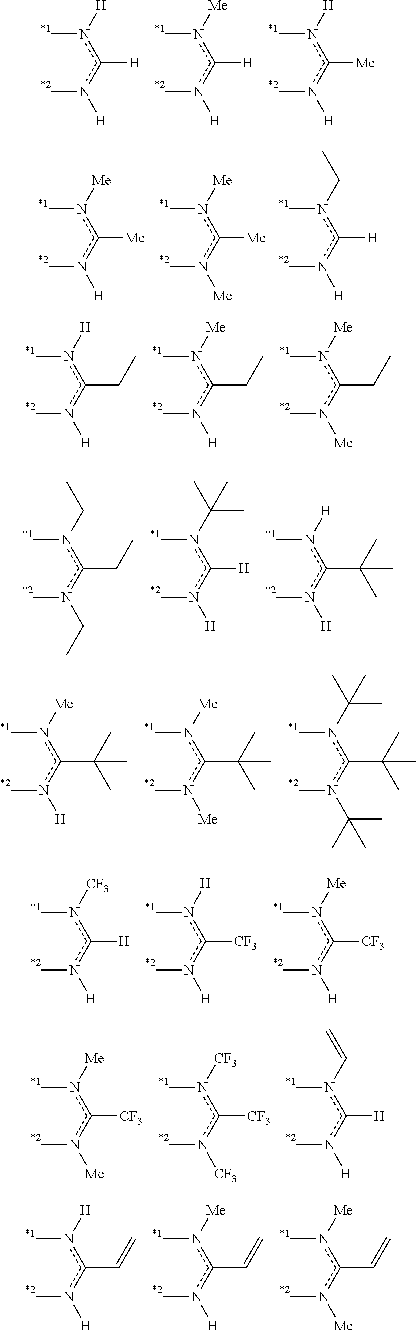

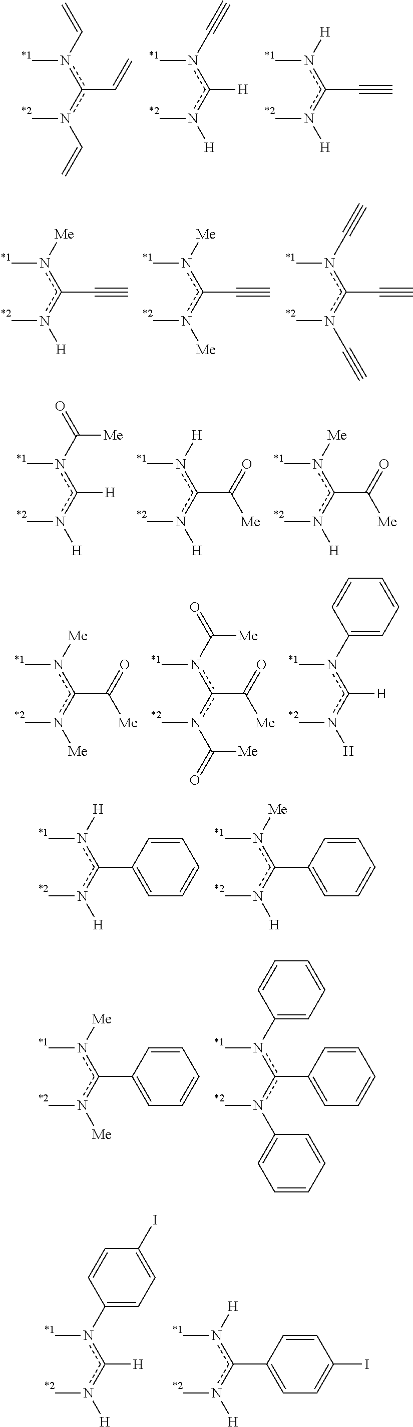

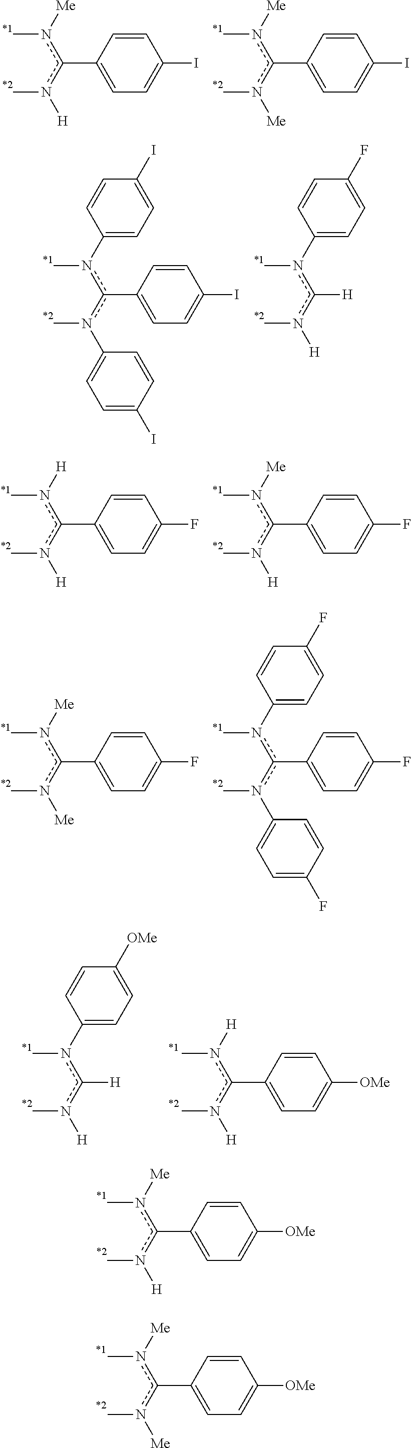

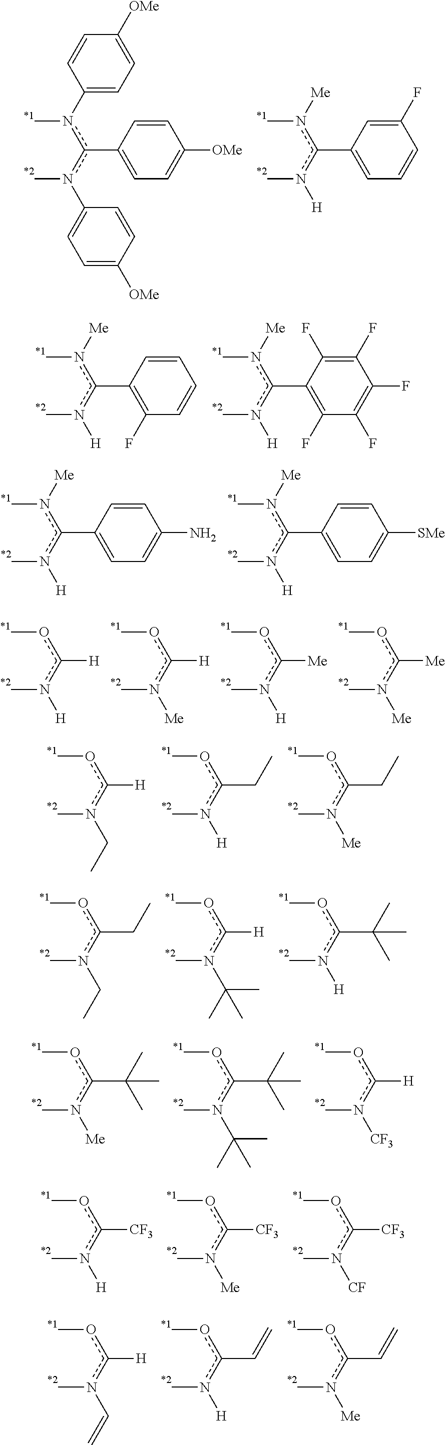

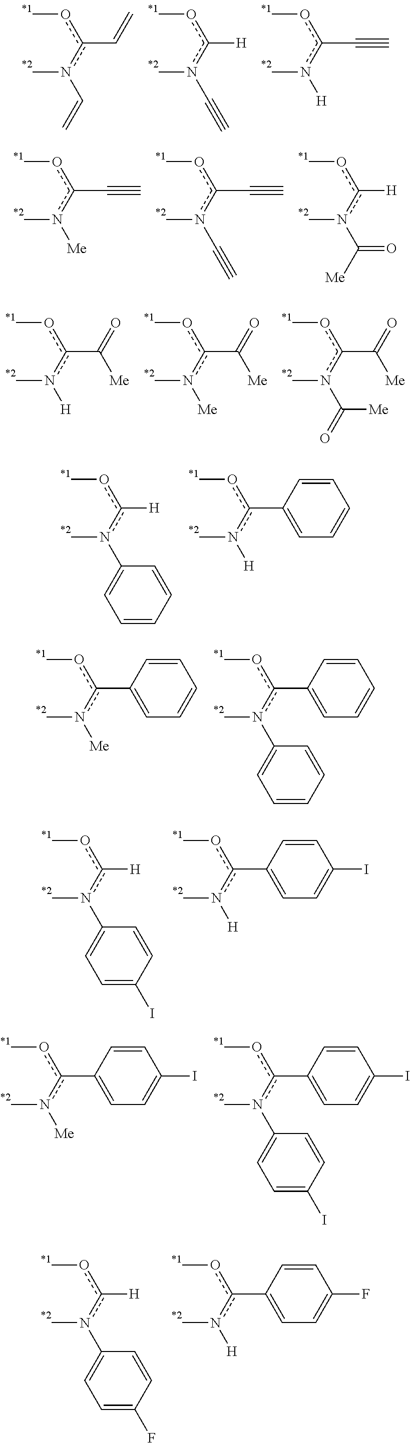

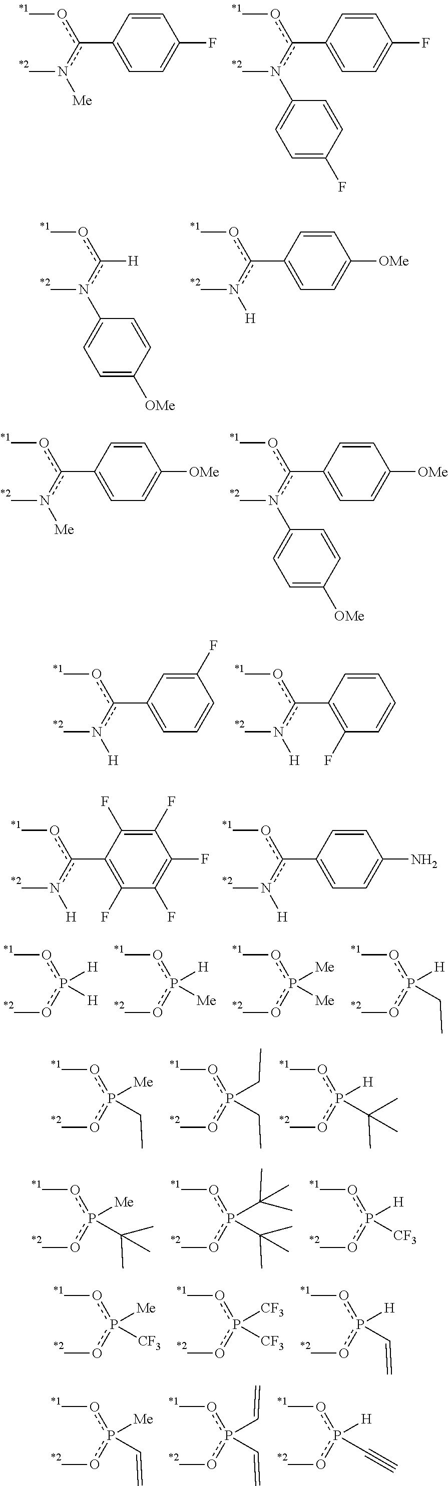

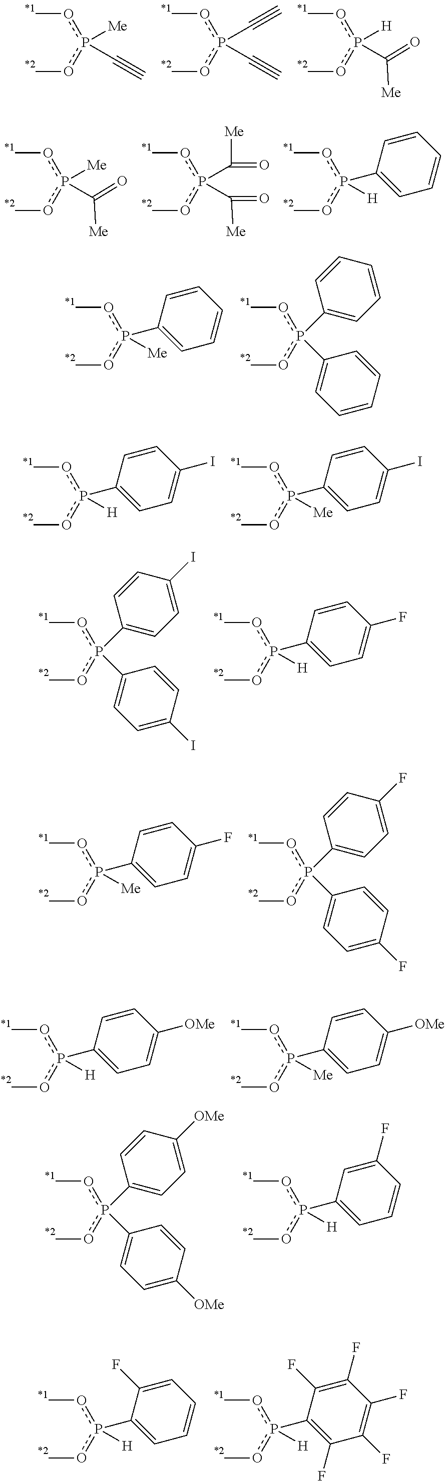

In addition to the ligand having formula (1a), (1b) or (1c), the metal complex may contain another ligand.

The other ligand may be a neutral ligand having a coordinating functional group such as an amino group, carboxy group, hydroxy group, ether bond, thiol group, thioether bond, cyano group, carbonyl group, phosphino group, imide group, pyridine ring or carbene, or an anionic ligand such as hydrido, amido, carboxylato, hydroxo, phenoxo, alkoxo, thiolato, cyanato, fluoro, iodo, chloro, bromo, oxo, alkyl, aryl, vinyl, alkynyl, or cyclopentadienyl. The other ligand may be unidentate or multidentate. Further, the other ligand may be a terminal ligand attached to a single metal atom or a bridging ligand attached to a plurality of metal atoms. Of the other ligands, anionic ligands are preferred, and anionic bridging ligands are more preferred. The other ligand may be used alone or in admixture.

The metal atom is preferably an element having a high absorption efficiency to EUV radiation, though not particularly limited. Suitable elements include Co, Ni, Cu, Zn, Ag, In, Sn, Sb, Te, and Pt. In view of synthesis, handling and availability of starting reactants, zinc (Zn) is preferred. Since zinc has a high EUV absorption efficiency, it is believed quite effective to apply the zinc complex to the EUV lithography.

Examples of the metal complex are shown below, but not limited thereto.

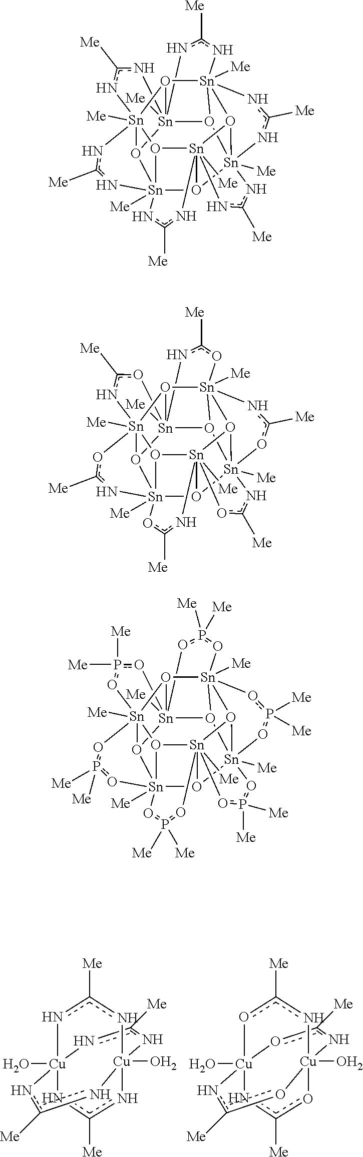

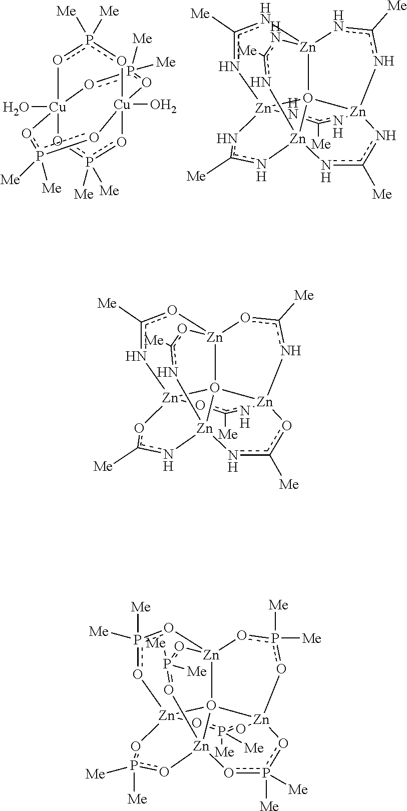

When the metal complex includes isomers depending on the arrangement of ligands, a mixture of such isomers or a single isomer may be used. When the metal complex contains ligands of different type, either a single metal complex wherein the ratio of ligands is completely controlled or a mixture of metal complexes wherein the ratio of ligands is different may be used.

The most preferred metal complex is a tetranuclear zinc cluster having the formula (2a). Since the zinc cluster contains zinc atoms having a high EUV absorption efficiency in a high density, it is excellent in sensitivity and resolution.

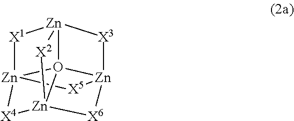

In formula (2a), X¹, X², X³, X⁴, X⁵ and X⁶ are each independently a bridging ligand. At least one of X¹ to X⁶ is a ligand having formula (1a), (1b) or (1c). Of X¹ to X⁶, the number of ligands having formula (1a), (1b) or (1c) is preferably from 1 to 6, more preferably from 3 to 6, most preferably 6.

Examples of the tetranuclear zinc cluster having formula (2a) are shown below, but not limited thereto.

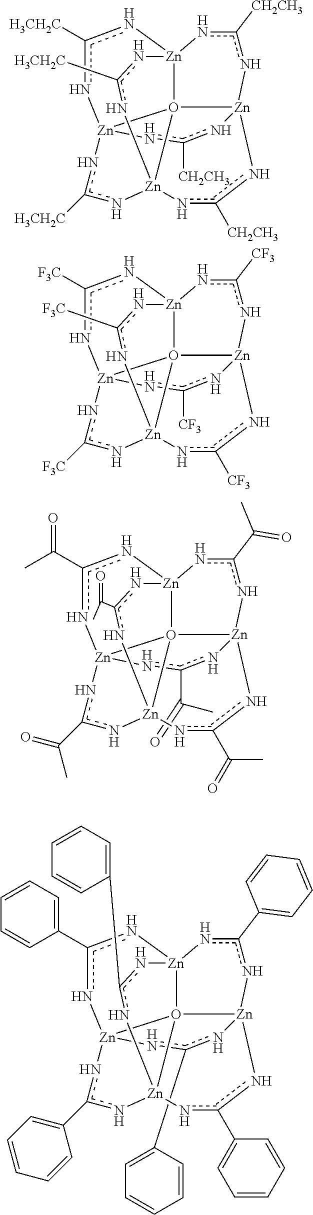

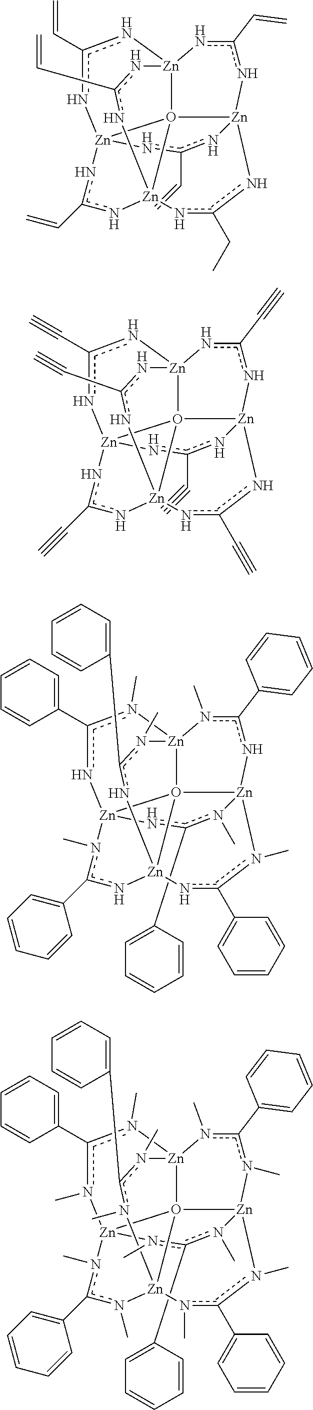

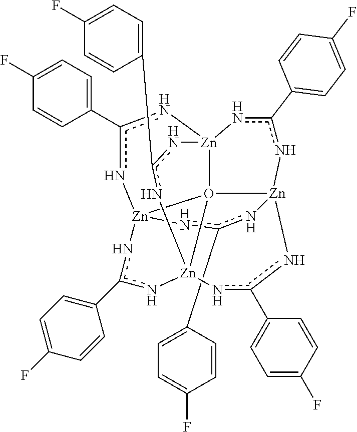

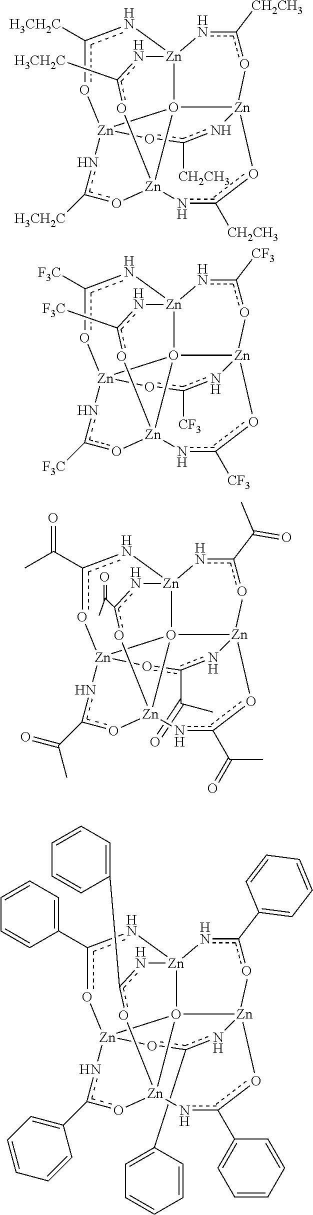

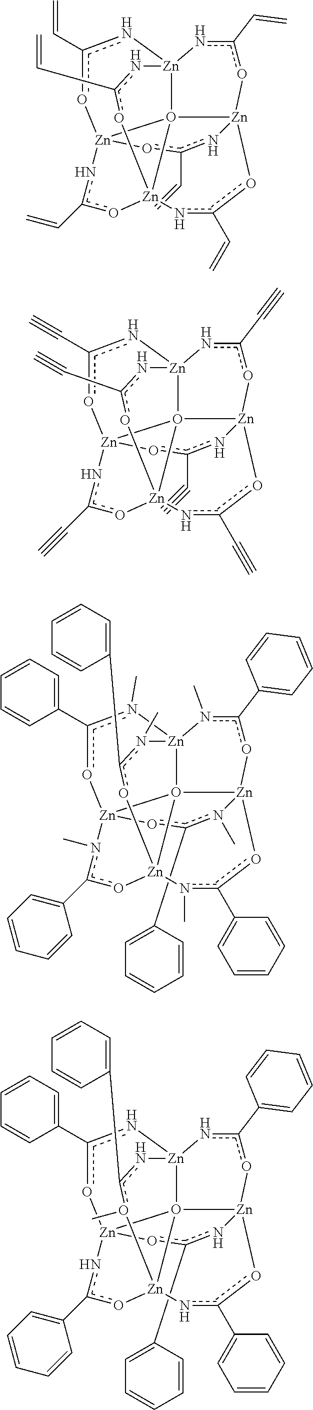

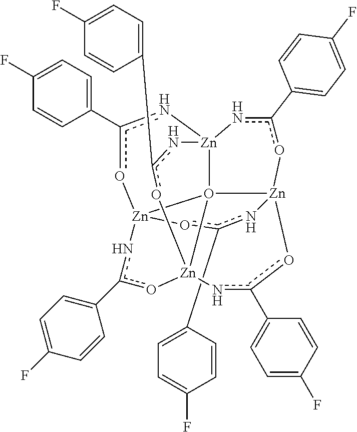

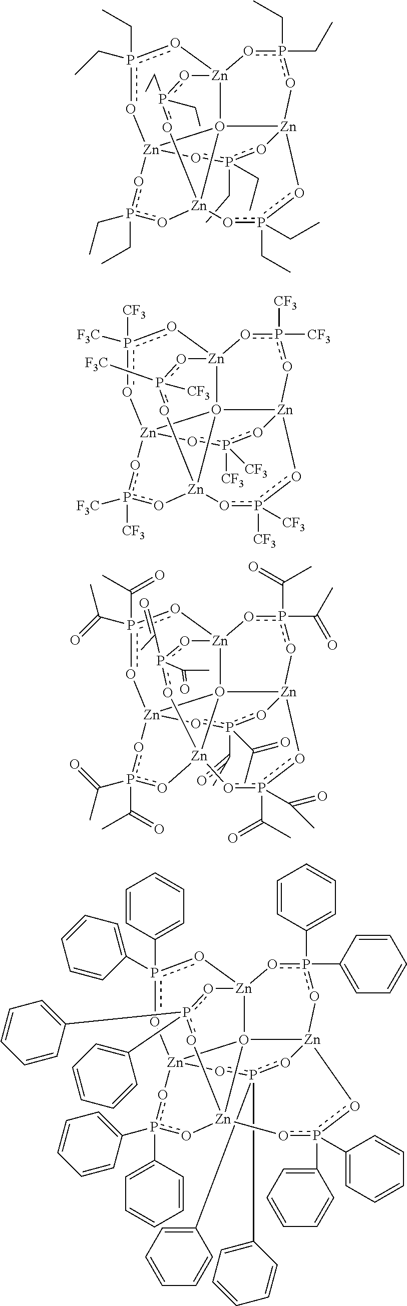

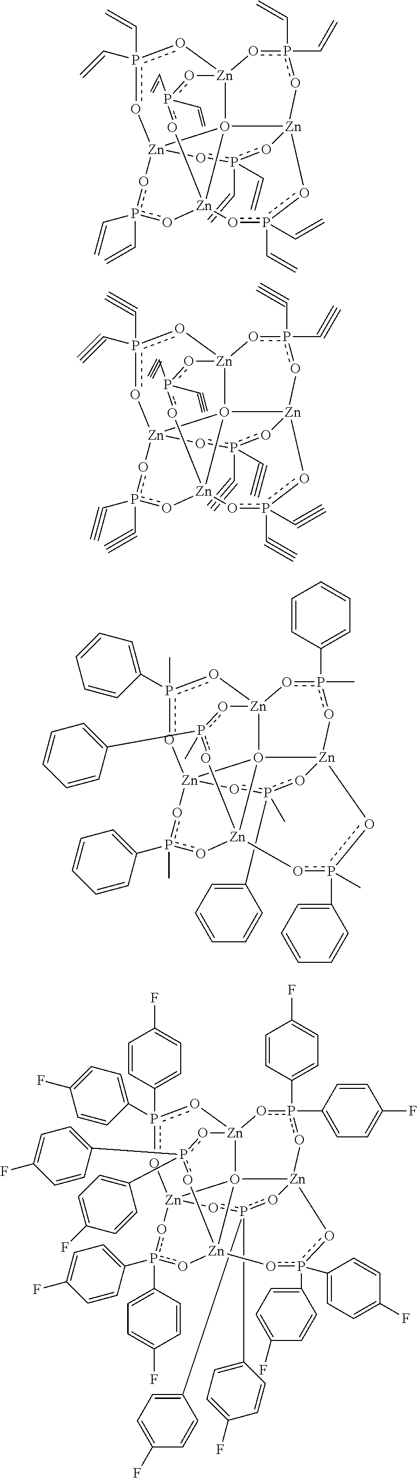

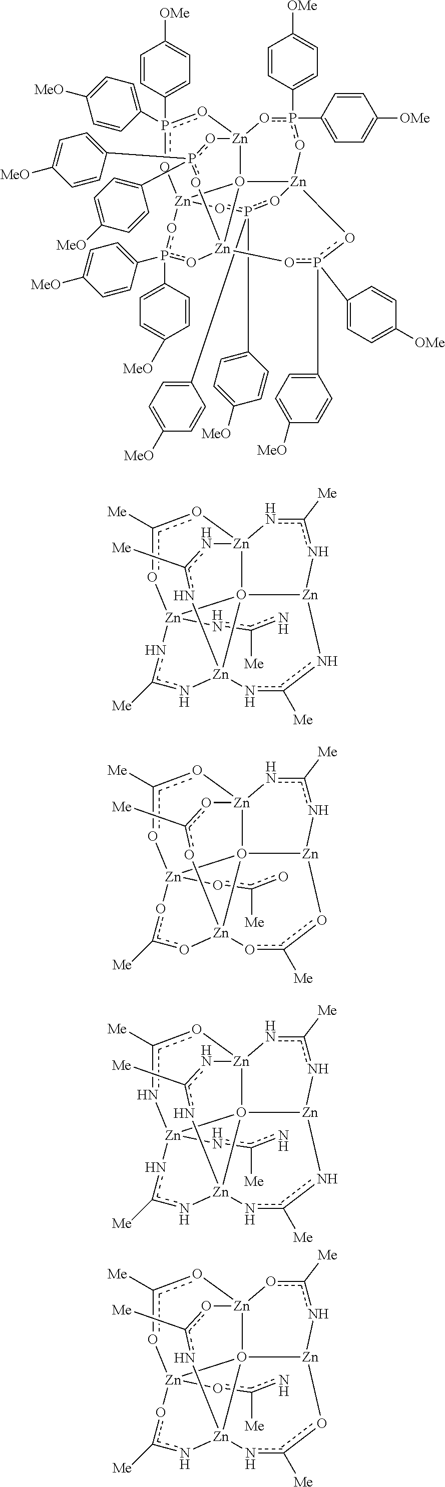

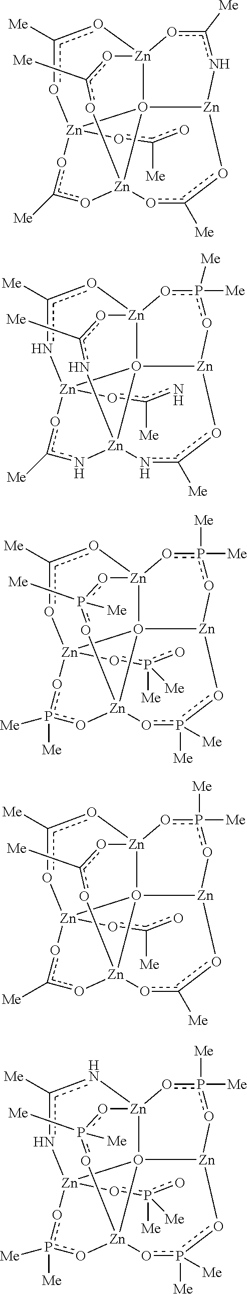

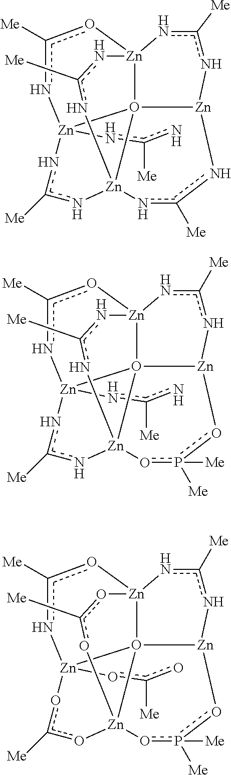

The metal complex may be used alone or in admixture of two or more.

### [Organic Solvent]

The resist composition may contain an organic solvent. The organic solvent is not particularly limited as long as the metal complex is dissolvable therein and a film can be formed from the resulting solution. Suitable organic solvents include ketones such as cyclohexanone and methyl 2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monomethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyronitrile; carboxylic acids such as acetic acid and propionic acid; aromatic solvents such as toluene, xylene, cresol, anisole and benzotrifluoride; halogenated hydrocarbons such as dichloromethane, chloroform and carbon tetrachloride, and mixtures thereof.

The amount of the organic solvent is preferably 200 to 20,000 parts by weight, more preferably 500 to 15,000 parts by weight per 100 parts by weight of the metal complex.

It is believed that the resist composition exhibits a contrast by the mechanism that the development resistance between exposed and unexposed regions changes by photo-decomposition of the metal complex and subsequent agglomeration or crosslinking reaction of partially broken metal complex pieces. Since this reaction is not a catalytic reaction, the resist composition functions as a non-chemically-amplified resist composition. This provides for a resolution even in a region of small feature size which is too small to form a pattern with conventional chemically amplified resist compositions based on a multi-component polymer. Particularly in the case of EUV lithography, since the metal atom has a high EUV absorptivity, the resist composition has improved stochastics as well as high sensitivity and reduced LWR. Also, since the metal complex converges to a thermally stable structure, it has high storage stability. There are no substantial changes of performance with the lapse of time after PEB.

### [Photoacid Generator]

In addition to the metal complex and organic solvent, the resist composition may contain a photoacid generator. Since the PAG generates an acid in the exposed region, the effect of the acid promoting crosslinking reaction of the metal complex is expectable. The PAG used herein is not particularly limited as long as it generates an acid upon exposure to high-energy radiation. Although the PAG used herein may be selected from well-known PAGs used in prior art chemically amplified resist compositions, those compounds capable of generating sulfonic acid, imidic acid (imide acid) or methide acid are preferred. Suitable PAGs include sulfonium salts, iodonium salts, sulfonyldiazomethane, N-sulfonyloxyimide, and oxime-O-sulfonate acid generators. Suitable PAGs are as exemplified in U.S. Pat. No. 7,537,880 (JP-A 2008-111103, paragraphs [0122]-[0142]) and US20220350243 (JP-A 2022-163697, paragraphs [0127]-[0193]).

When the resist composition contains a PAG, the amount of PAG is preferably 0.01 to 20% by weight based on the overall solids. As used herein, the term “solids” refers to all components other than the solvent in the resist composition. The PAG may be used alone or in admixture.

### [Radical Scavenger]

The resist composition may further contain a radical scavenger (or radical trapping agent) as an additional component. The radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When used, the radical scavenger is preferably present in an amount of 0.01 to 10% by weight based on the overall solids. The radical scavenger may be used alone or in admixture.

### [Surfactant]

The resist composition may further contain a surfactant. For the surfactant, reference should be made to those compounds described in JP-A 2010-215608 and JP-A 2011-016746. While many examples of the surfactant are described in the patent documents cited herein, preferred examples are fluorochemical surfactants FC-4430 (3M), Olfine® E1004 (Nissin Chemical Co., Ltd.), Surflon® S-381, KH-20 and KH-30 (AGC Seimi Chemical Co., Ltd.). Partially fluorinated oxetane ring-opened polymers having the formula (surf-1) are also useful.

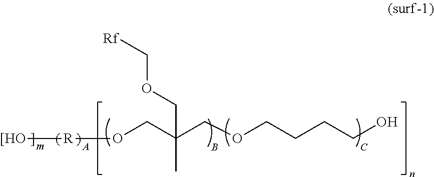

In formula (surf-1), R is a di-to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

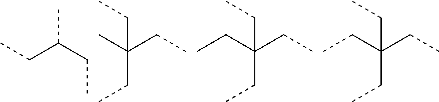

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferred.

Rf is trifluoromethyl or pentafluoroethyl, and preferably trifluoromethyl. The subscript m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

When the resist composition contains the surfactant, it is preferably used in an amount of 0.001 to 20 parts by weight, more preferably 0.1 to 10 parts by weight per 100 parts by weight of the metal complex. The surfactant may be used alone or in admixture.

### [Pattern Forming Process]

When the resist composition is used in the fabrication of various integrated circuits, any well-known lithography techniques are applicable. For example, the invention provides a pattern forming process comprising the steps of applying the resist composition onto a substrate to form a resist film thereon, exposing the resist film to high-energy radiation, and developing the exposed resist film.

First, the resist composition is applied onto a substrate for integrated circuit fabrication (e.g., Si, SiO₂, SiN, SiON, TiN, WSi, BPSG, SOG, or organic antireflective coating) or a substrate for mask circuit fabrication (e.g., Cr, CrO, CrON, MoSi₂, or SiO₂) by any suitable technique such as spin coating, roll coating, flow coating, dip coating, spray coating or doctor coating. The coating is prebaked (PAB) on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm.

Next the resist film is exposed to high-energy radiation. The radiation is selected from among UV, deep UV, EB, EUV of wavelength 3 to 15 nm, X-ray, soft X-ray, excimer laser radiation, Y-ray, and synchrotron radiation. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 200 mJ/cm², more preferably about 10 to 150 mJ/cm². On use of EB as the high-energy radiation, imagewise writing is performed directly or through a mask having the desired pattern so as to reach a dose of preferably about 0.1 to 5,000 μC/cm², more preferably about 0.5 to 4,000 μC/cm². The resist composition is best suited in micropatterning using EB or EUV as the high-energy radiation.

The resist film may be post-exposure baked (PEB) to promote or complete the reaction after photo-decomposition. Preferably PEB is performed on a hot plate or in an oven at 30 to 200° C. for 10 seconds to 30 minutes, more preferably at 60 to 180° C. for 30 seconds to 20 minutes.

After the exposure or PEB, the resist film is developed. The development may be either wet or dry development. In the case of wet development, alkaline development or organic solvent development is applicable. When the resist composition is developed to form a pattern, organic solvent development is preferred. In the case of wet development, the exposed resist film is developed by a standard technique such as dip, puddle or spray technique for 3 seconds to 3 minutes, more preferably 5 seconds to 2 minutes whereby the desired pattern is formed. Since the resist composition is of negative tone, the exposed region is insolubilized in the developer whereas the unexposed region is dissolved away.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, dichloromethane, chloroform, carbon tetrachloride, formic acid, acetic acid, and propionic acid. The organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene. The solvents may be used alone or in admixture.

Rinsing is effective for minimizing the risks of resist pattern collapse and defect formation. However, rinsing is not essential. If rinsing is omitted, the amount of solvent used may be reduced.

In the development step of the pattern forming process, dry development is also applicable. The dry development is the step of etching a resist film with a gas etchant to remove the exposed or unexposed region of the resist film, without using a developer. In the practice of the invention, the unexposed region of a resist film of the resist composition is etched away with the gas etchant to form the desired pattern. For the dry etching, a mixture of a gas containing oxygen, hydrogen, ammonia or halogen and a diluent gas such as nitrogen, helium, argon, carbon dioxide or carbon monoxide is preferably used.

### Examples

Examples of the invention are given below by way of illustration and not by way of limitation. The abbreviation “pbw” is parts by weight.

In Examples, metal complexes having the formulae (M-1) to (M-3) were used.

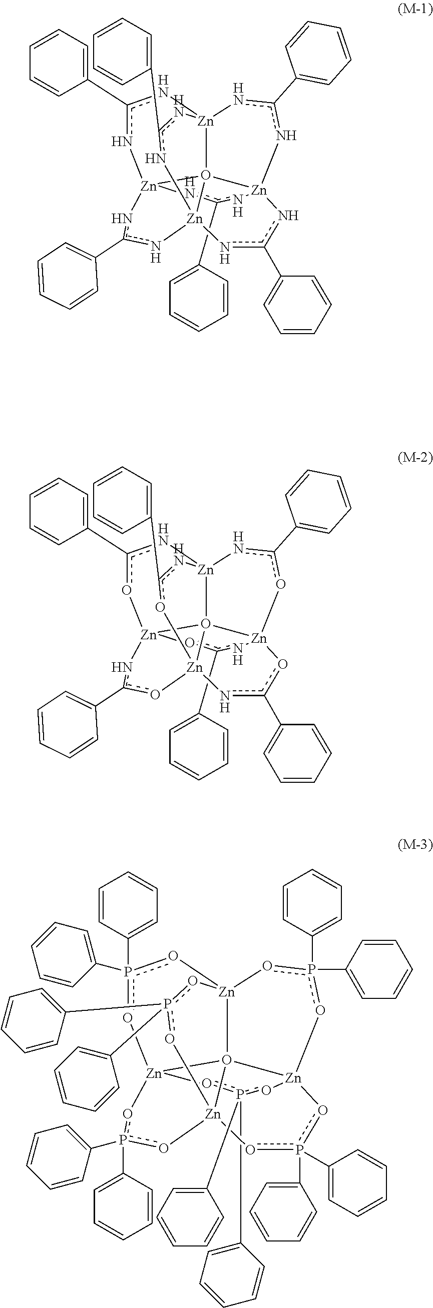

The metal complex having formula (M-1) was synthesized with reference to Communications Chemistry, 2021, 4, 133. The metal complex having formula (M-2) was synthesized with reference to Inorganic Chemistry, 2022, 61, 7869-7877. The metal complex having formula (M-3) was synthesized with reference to Nature Communications, 2016, 7, 13008.

### [1] Preparation of Resist Composition

### Examples 1-1 to 1-5 and Comparative Example 1-1

Resist compositions (R-1 to R-5 and CR-1) were prepared by dissolving the selected components in a solvent in accordance with the recipe shown in Table 1, and filtering the solution through a Teflon® filter having a pore size of 0.2 μm.

TABLE 1

| | | Resist | Component A | Component B | Component C | Solvent |
|---|---|---|---|---|---|---|
| | | composition | (pbw) | (pbw) | (pbw) | (pbw) |
| Example | 1-1 | R-1 | M-1 (20.0) | — | — | chloroform (1000) |
| | 1-2 | R-2 | M-2 (20.1) | — | — | chloroform (1000) |
| | 1-3 | R-3 | M-3 (31.9) | — | — | chloroform (1000) |
| | 1-4 | R-4 | M-2 (20.1) | P-1 (19) | — | chloroform (1000) |
| | 1-5 | R-5 | M-2 (20.1) | — | Sc-1 (0.01) | chloroform (1000) |
| Comparative | 1-1 | CR-1 | CM-1 (20) | — | — | chloroform (1000) |
| Example | | | | | | |

In Table 1, component A is a metal complex, component B is a photoacid generator, and component C is a radical scavenger. Compounds (M-1) to (M-3) used as component A has the structure described above. Components B and C are identified below.
P-1: triphenylsulfonium tosylate
Sc-1: dibutylhydroxytoluene

The tin compound CM-1 used in Comparative Example 1-1 was synthesized with reference to Angewandte Chemie, International Edition (2017), 56 (34), 10140-10144. CM-1 has the following structure.

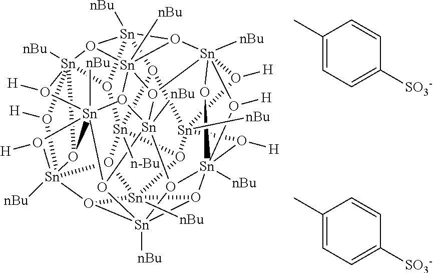

### [2] EB Lithography Test

### Examples 2-1 to 2-5 and Comparative Example 2-1

Each of the resist compositions (R-1 to R-5 and CR-1) was spin coated on a silicon substrate having an antireflective film of 60 nm thick (DUV-42 by Nissan Chemical Corp.) and pre-baked (PAB) on a hotplate at 100° C. for 60 seconds to form a resist film of 40 nm thick. Using an electron beam lithography system ELS-F125 (Elionix Inc., accelerating voltage 125 kV), the resist film was exposed to EB. The resist film was baked (PEB) on a hotplate at the temperature shown in Table 2 for 60 seconds and developed in 2-heptanone for 30 seconds to form a line-and-space (LS) pattern of negative tone having a space width of 20 nm and a pitch of 40 nm.

The LS pattern was observed under CD-SEM (CG-5000 or CG-6300, Hitachi High-Technologies Corp.) and evaluated for sensitivity, LWR and maximum resolution by the following methods. The results are shown in Table 2.

### Evaluation of Sensitivity

The optimum dose (Eop, μC/cm²) which provided an LS pattern with a space width of 20 nm and a pitch of 40 nm was determined and reported as sensitivity.

### Evaluation of LWR

An LS pattern was formed by exposure in the optimum dose (Eop). The space width was measured at longitudinally spaced apart 10 points, from which a 3-fold value (30) of the standard deviation (o) was determined and reported as LWR. A smaller value indicates a pattern having a lower roughness and more uniform space width.

### Evaluation of Maximum Resolution

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

### Evaluation of PPD Stability

After exposure at the optimum dose, PEB and development were performed under the conditions shown below. A wafer in which a pattern was formed by development without any delay after PEB is designated PPD 0h. A wafer in which a pattern was formed by development at a delay of 6 hours after PEB is designated PPD 6 h. The line width of these wafers was measured under CD-SEM (CG-6300, Hitachi High-Technologies Corp.). A change (ΔPPD) of line width (CD) by PPD was determined. The results are shown in Table 2.

TABLE 2

| | | | | | | Maximum | PPD 0 h | PPD 6 h | ΔPPD |
|---|---|---|---|---|---|---|---|---|---|
| | | Resist | PEB | Eop | LWR | resolution | CD | CD | CD |
| | | composition | (° C.) | (μC/cm²) | (nm) | (nm) | (nm) | (nm) | (nm) |
| Example | 2-1 | R-1 | 150 | 2500 | 3.2 | 13.3 | 19.9 | 20.5 | 0.6 |
| | 2-2 | R-2 | 150 | 2400 | 3.3 | 14.2 | 20.0 | 20.4 | 0.4 |
| | 2-3 | R-3 | 150 | 2200 | 3.1 | 12.9 | 20.1 | 20.2 | 0.1 |
| | 2-4 | R-4 | 150 | 2200 | 3.4 | 14.5 | 20.2 | 21.0 | 0.8 |
| | 2-5 | R-5 | 150 | 2600 | 3.4 | 12.5 | 20.0 | 20.7 | 0.7 |
| Comparative | 2-1 | CR-1 | 170 | 3200 | 4.7 | 18.6 | 20.1 | 25.2 | 5.1 |
| Example | | | | | | | | | |

As is evident from Table 2, the resist compositions within the scope of the invention show excellent LWR and maximum resolution in forming negative patterns through organic solvent development according to the EB lithography. The change of CD by PPD is small, indicating that the resist film is stable after pattern formation. Since the resist compositions contain a high density of zinc atoms having a high EUV absorptivity, a remarkably high sensitivity in the EUV lithography is expectable.

### [3] Evaluation of Storage Stability

### Examples 3-1 to 3-5 and Comparative Example 3-1

The resist compositions (R-1 to R-5 and CR-1) were held at normal temperature (20±5° C.) for a certain period, after which they were visually observed to examine whether or not precipitates formed. The composition in which no precipitates formed on storage for more than 6 months is rated Pass (O). The composition in which precipitates formed on storage for less than 6 months is rated Reject (X). The results are shown in Table 3.

TABLE 3

| | | Resist composition | Storage stability |
|---|---|---|---|
| Example | 3-1 | R-1 | ∘ |
| | 3-2 | R-2 | ∘ |
| | 3-3 | R-3 | ∘ |
| | 3-4 | R-4 | ∘ |
| | 3-5 | R-5 | ∘ |
| Comparative Example | 3-1 | CR-1 | x |

As seen from Table 3, the resist compositions within the scope of the invention are stable during storage and easy to handle.

Japanese Patent Application No. 2024-091409 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a metal complex containing a metal atom and a ligand having the formula (1a), (1b) or (1c): 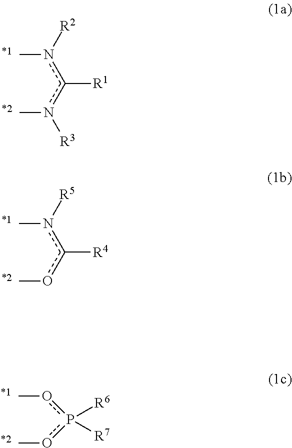
wherein R¹, R², R³, R⁴, R⁵, R⁶ and R⁷ are each independently hydrogen, a C₂-C₂₀ hydrocarbylcarbonyl group which may contain a heteroatom, or C₁-C₂₀ hydrocarbyl group which may contain a heteroatom, *1 and *2 each designate a point of attachment to the metal atom.

2. The resist composition of claim 1 wherein the metal atom is zinc.

3. The resist composition of claim 1 wherein the metal complex is a tetranuclear zinc cluster having the formula (2a): 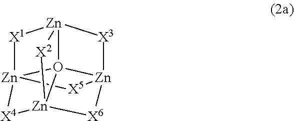
wherein X¹, X², X³, X⁴, X⁵ and X⁶ are each independently a bridging ligand, at least one of X¹, X², X³, X⁴, X⁵ and X⁶ is a ligand having formula (1a), (1b) or (1c).

4. A pattern forming process comprising the steps of applying the resist composition of claim 1 onto a substrate to form a resist film thereon, exposing the resist film to high-energy radiation, and developing the exposed resist film.

5. The pattern forming process of claim 4 wherein the high-energy radiation is EB or EUV.
